(19) United States
(12) Patent Application Publication
(10) Pub. No.: US 2025/0112070 A1
(43) Pub. Date: Apr. 3, 2025

(54) WAFER STORAGE CONTAINER PROCESSING APPARATUS

(71) Applicant: SHIBAURA MECHATRONICS CORPORATION, Kanagawa (JP)

(72) Inventors: Junji ISHIHARA, Kanagawa (JP); Hisaaki MIYASAKO, Kanagawa (JP); Yukinobu NISHIBE, Kanagawa (JP)

(21) Appl. No.: 18/894,512

(22) Filed: Sep. 24, 2024

(30) Foreign Application Priority Data
Sep. 28, 2023 (JP) 2023-168678

(51) Int. Cl. H01L 21/673

(52) U.S. Cl. CPC H01L 21/67389; H01L 21/67373

(57) ABSTRACT

According to one embodiment, a wafer storage container processing apparatus that processes a wafer storage container including a body having a storage space connected to an opening and a door detachable from the opening, includes a stage having a disposition surface on which the wafer storage container is disposed; and a gas supply configured to supply an inert gas to the wafer storage container disposed on the stage. The stage disposes the wafer storage container such that the door is disposed on the disposition surface in a state where the door is attached to the body, and the gas supply supplies the inert gas through a gas supply port provided on an intersecting surface of the body that intersects a surface having the opening.

### CROSS-REFERENCE TO RELATED APPLICATIONS

This application is based on and claims priority from Japanese Patent Application No. 2023-168678 filed on Sep. 28, 2023 with the Japan Patent Office, the disclosure of which is incorporated herein in its entirety by reference.

### TECHNICAL FIELD

The present disclosure relates to a wafer storage container processing apparatus.

### BACKGROUND

In the related art, a wafer storage container processing apparatus performs various processes such as cleaning and drying on wafer storage containers such as front opening unified pods (FOUPs) that accommodate semiconductor wafers.

There is a technique for replacing a gas in a storage space that stores the wafers in the FOUP, by supplying an inert gas such as N₂ to the storage space, in a state where the door is attached to the body (shell) of the FOUP. For example, a supply port through which the inert gas is supplied and a discharge port through which the gas in the storage space is discharged, are provided on the bottom 20i of the shell 20a as illustrated in FIG. 8.

The accuracy of FOUPs tends to vary depending on the manufacturer. Therefore, in some of the FOUPs, as illustrated in FIG. 8, a small gap 20j may occur between the shell 20a and the door 20b. In addition, due to the age-related deterioration and other factors, in some of the FOUPs, a small gap 20j may occur between the shell 20a and the door 20b. Therefore, when replacing the gas in the storage space, the inert gas supplied from the supply port may leak through the gap 20j. In this case, the gas in the storage space may not be replaced efficiently. Such a problem exists not only in the FOUPs, but also in other wafer storage containers such as front opening shipping boxes (FOSBs). See, for example, Japanese Patent Laid-Open Publication No. 2005-109523.

### SUMMARY

The present disclosure provides a wafer storage container processing apparatus capable of efficiently replacing a gas in a wafer storage container.

A wafer storage container processing apparatus according to an embodiment of the present disclosure processes a wafer storage container including a body having a storage space connected to an opening and a door detachable from the opening. The wafer storage container processing apparatus includes a stage having a disposition surface on which the wafer storage container is disposed; and a gas supply that supplies an inert gas to the wafer storage container disposed on the stage. The stage disposes the wafer storage container thereon such that the door is disposed on the disposition surface in a state where the door is attached to the body, and the gas supply supplies the inert gas through a gas supply port provided on an intersecting surface of the body that intersects a surface having the opening.

According to an embodiment of the present disclosure, it is possible to provide a wafer storage container processing apparatus capable of efficiently replacing gas in a storage space.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view illustrating an example of a schematic configuration of a wafer storage processing apparatus according to an embodiment.

FIG. 2 is a perspective view of a lock/unlock stage according to an embodiment.

FIG. 3 is a perspective view of a lock/unlock stage according to an embodiment.

FIG. 4 is a side view of a lock/unlock stage according to an embodiment.

FIG. 5 is a view for explaining an example of an arrangement of slots according to an embodiment.

FIG. 6 is a flowchart illustrating an example of a purging process performed by the wafer storage processing apparatus according to an embodiment.

FIG. 7 is a side view of a lock/unlock stage according to a modification of the embodiment.

FIG. 8 is a view illustrating an example of a configuration of a wafer storage container.

### DESCRIPTION OF EMBODIMENTS

In the following detailed description, reference is made to the accompanying drawing, which form a part hereof. The illustrative embodiments described in the detailed description, drawings, and claims are not meant to be limiting. Other embodiments may be utilized, and other changes may be made without departing from the spirit or scope of the subject matter presented here.

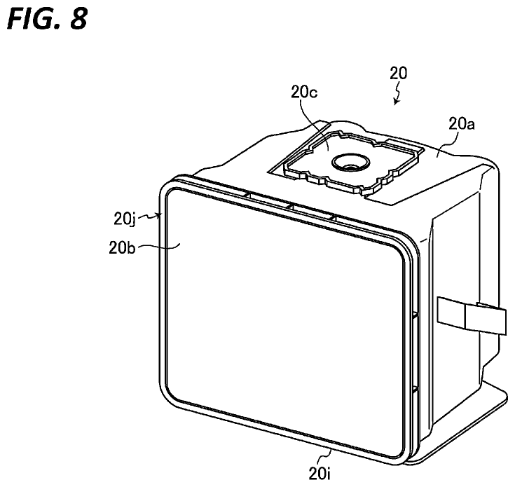

Hereinafter, embodiments of a wafer storage container processing apparatus disclosed herein are described in detail with reference to the accompanying drawings. The wafer storage container processing apparatus disclosed herein is not limited to the following embodiments. In the following embodiments, a wafer storage container to be subjected to various processes such as cleaning and drying is described as a FOUP, but the wafer storage container to be subjected to various processes is not limited thereto. For example, the wafer storage container to be subjected to various processes may be a FOSB. The FOUP is provided with a flange 20c (see, e.g., FIG. 8), and the FOUP is transported by a robot grasping the flange 20c.

### Embodiment

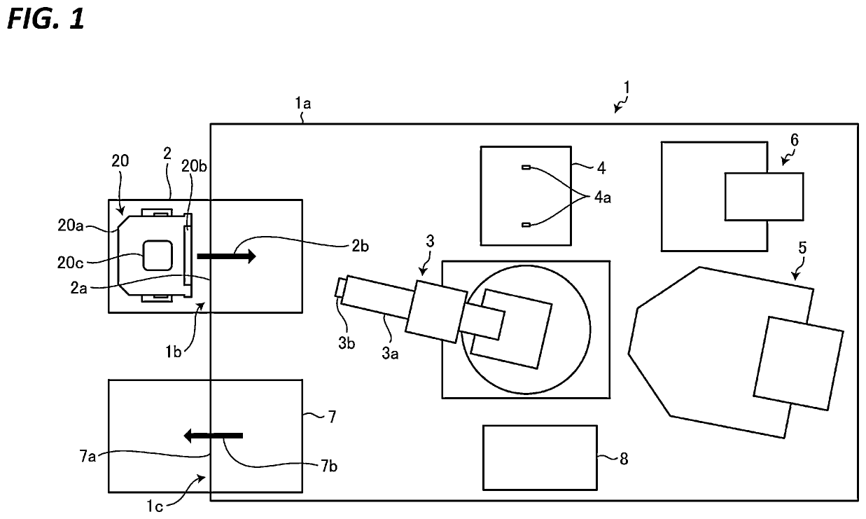

FIG. 1 is a plan view illustrating an example of a schematic configuration of a wafer storage processing apparatus 1 according to an embodiment. The wafer storage container processing apparatus 1 is installed, for example, in a factory that manufactures semiconductor wafers, and cleans and dries wafer storage containers.

As illustrated in FIG. 1, the wafer storage container processing apparatus 1 includes a load port 2, a robot 3, a lock/unlock stage 4, a cleaning chamber 5, a drying chamber 6, an unload port 7, and a control unit 8.

The robot 3, the lock/unlock stage 4, the cleaning chamber 5, the drying chamber 6, and the control unit 8 are provided inside a casing 1a of the wafer storage container processing apparatus 1. Meanwhile, the load port 2 and the unload port 7 are provided across the inside and outside of the casing 1a of the wafer storage container processing apparatus 1.

The load port 2 carries the FOUP 20 to be cleaned and dried, which is disposed on the outside of the casing 1a of the load port 2, into the inside of the casing 1a. The FOUP 20 includes a shell 20a, which is the FOUP body, and a door 20b. The shell 20a has an opening (shell opening) and a storage space for storing semiconductor wafers. The storage space is located inside the shell opening and communicates with the shell opening. The door 20b is lockable/unlockable with the shell 20a. The door 20b is attachable to and detachable from the shell opening. The shell 20a is an example of the body. The shell 20a is provided with a flange 20c. The flange 20c is a part that is grasped (held) when the FOUP 20 is transported by an overhead hoist transport (OHT) or a robot 3, and is provided on a surface that intersects with a surface of the shell 20a that has the shell opening.

For example, the FOUP 20 transported by the OHT is disposed on the outside of the casing 1a of the load port 2. For example, as illustrated in FIG. 1, the FOUP 20 is disposed such that the door 20b of the FOUP 20 faces a shutter 2a provided at the opening 1b of the casing 1a. When the FOUP 20 is disposed on the load port 2 in this manner, the shutter 2a is raised. As a result, the FOUP 20 may be carried into the casing 1a from the opening 1b. That is, the FOUP 20 becomes ready to be carried into the wafer storage container processing apparatus 1. Then, the FOUP 20 is slid in the direction of an arrow 2b by a slide device of the load port 2. As a result, the FOUP 20 is carried into the casing 1a.

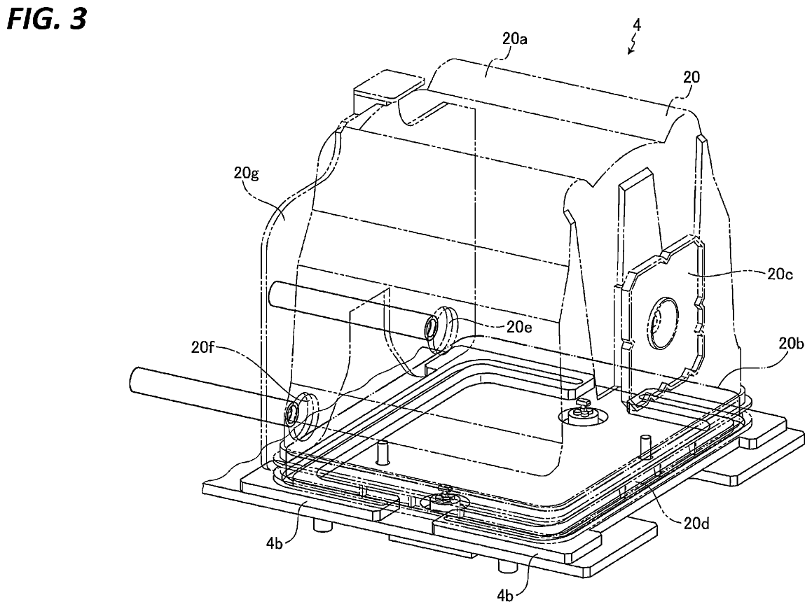

The sliding by the sliding device is described. For example, a pin provided on the sliding device is inserted into a hole provided on a bottom surface 20g (see, e.g., FIG. 3) of the FOUP 20, so that the bottom surface 20g of the FOUP 20 is fixed to the sliding device. In this state, when the sliding device is slid in the direction of the arrow 2b, the FOUP 20 is also slid along with the movement of the sliding device. As a result, the FOUP 20 is disposed on a predetermined portion inside the casing 1a of the load port 2. When the FOUP 20 is carried into the inside of the casing 1a in this manner, the shutter 2a is lowered, so that the opening 1b of the casing 1a is closed. The sliding device moves down together with the pin to a position lower than the lower end of the shutter 2a (the bottom surface 20g of the FOUP 20) and returns to the original position outside the casing 1a.

The robot 3 transports the FOUP 20 to each section while gripping the flange 20c of the FOUP 20. The robot 3 includes a robot arm 3a and a robot hand 3b (a gripping unit of the robot 3). The robot 3 transports the FOUP 20 to each section by extending, contracting, and rotating the robot arm 3a while the robot hand 3b is grasping the flange 20c. When the robot 3 transports the door 20b alone that has been separated (unlocked) from the shell 20a, the robot 3 transports the door 20b by gripping both sides of the door 20b.

The lock/unlock stage 4 is an example of a stage. For example, the lock/unlock stage 4 is a stage on which the FOUP 20 is disposed, and separates (unlocks) the FOUP 20 into a shell 20a and a door 20b, and connects (locks) the shell 20a and the door 20b. For example, the FOUP 20 that has been carried into the casing 1a is transported to the lock/unlock stage 4 by the robot 3. At this time, the lock/unlock stage 4 separates the FOUP 20 into the shell 20a and the door 20b.

The cleaning chamber 5 is a chamber for cleaning the FOUP 20. For example, the shell 20a and the door 20b are transported separately to the cleaning chamber 5 by the robot 3. Then, the cleaning chamber 5 performs a cleaning process on the FOUP 20 while holding the shell 20a and the door 20b separately. That is, the cleaning chamber 5 cleans the storage space while the shell 20a and the door 20b are separated. For example, the cleaning chamber 5 holds the door 20b in the lid portion of the cleaning chamber 5 and the shell 20a in the chamber portion of the cleaning chamber 5 (the cleaning chamber body of the cleaning chamber 5), and while rotating them by a rotation mechanism (not illustrated), a cleaning liquid (e.g., deionized water) is discharged from a cleaning liquid nozzle onto each of the shell 20a and the door 20b, thereby cleaning the FOUP 20. In the cleaning chamber 5, the shell 20a may be arranged such that the shell opening faces downward, taking into consideration the efficiency of discharging the cleaning liquid. The cleaning chamber 5 is an example of a cleaning section.

When cleaning of the FOUP 20 is completed in the cleaning chamber 5, the shell 20a and door 20b are then rotated in the cleaning chamber 5 and dried by blowing dry air thereto. The drying in the cleaning chamber 5 is a process for removing the cleaning liquid adhering to the FOUP 20 (temporary drying). When the temporary drying of the FOUP 20 in the cleaning chamber 5 is completed, the robot 3 transports the shell 20a and door 20b in the cleaning chamber 5 separately to the drying chamber 6.

The drying chamber 6 is a device for vacuum drying the FOUP 20 (main drying). When the vacuum drying of the FOUP 20 is completed in the drying chamber 6, the robot 3 transports the shell 20a and the door 20b in the drying chamber 6 separately onto the lock/unlock stage 4. Then, the lock/unlock stage 4 connects the shell 20a and the door 20b. In the embodiment, after the main drying in the drying chamber 6, an inert gas such as N₂ is supplied to the storage space of the FOUP 20 in which the shell 20a and the door 20b are connected on the lock/unlock stage 4, thereby replacing the gas in the storage space. Such a gas replacement process is also called a purging process. The configuration of the lock/unlock stage 4 and a specific example of the purging process performed by the lock/unlock stage 4 is described later.

The unload port 7 carries out the FOUP 20 that has been cleaned, vacuum-dried, and purged and that has been disposed by the robot 3 in a portion inside the casing 1a of the unload port 7, to the outside of the casing 1a.

For example, after the purging process, the FOUP 20 is transported by the robot 3 and disposed in a portion inside the casing 1a of the unload port 7. When the FOUP 20 is disposed in the unload port 7 in this manner, the shutter 7a provided at the opening 1c of the casing 1a is raised. As a result, the FOUP 20 may be carried out from the opening 1c to the outside of the casing 1a. That is, the FOUP 20 becomes ready to be carried out to the outside of the wafer storage container processing apparatus 1. Then, the FOUP 20 is slid in the direction of an arrow 7b by the slide device of the unload port 7 (having the same mechanism as the slide device of the load port 2), and the FOUP 20 is carried out to the outside of the casing 1a. When the FOUP 20 is carried out to the outside of the casing 1a in this manner, the shutter 7a is lowered, so that the opening 1c of the casing 1a is closed.

The controller 8 controls the overall operation of the wafer storage container processing apparatus 1. For example, the control unit 8 controls the load port 2, the robot 3, the lock/unlock stage 4, the cleaning chamber 5, the drying chamber 6, and the unload port 7, thereby operating the load port 2, the robot 3, the lock/unlock stage 4, the cleaning chamber 5, the drying chamber 6, and the unload port 7 as described above. In addition, the control unit 8 controls a gas supply nozzle 4c, valves 4e1, 4f1, 4j1, and a measurement unit 4h, which will be described later.

For example, the control unit 8 includes a central processing unit (CPU), a read only memory (ROM), a random access memory (RAM), a hard disk drive (HDD), and a communication interface. These are connected via an internal bus.

The CPU executes various processes while using the memory area of the RAM as a temporary storage area for data used in the various processes. The ROM and HDD store programs for executing various processes such as the above-mentioned purging process, and various databases and tables used when executing the various processes. The communication interface is an interface for communicating with the above-mentioned units of the wafer storage container processing apparatus 1, and also for communicating with external devices connected to the wafer storage container processing apparatus 1 via a network. For example, the communication interface is a network interface card.

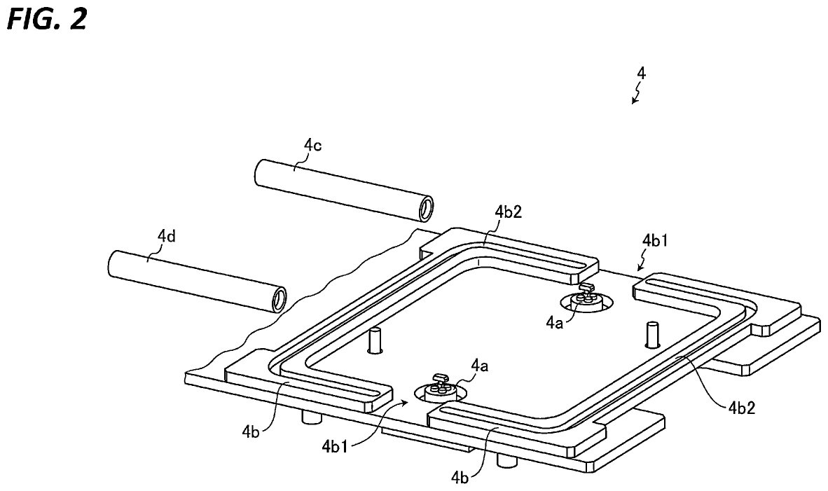

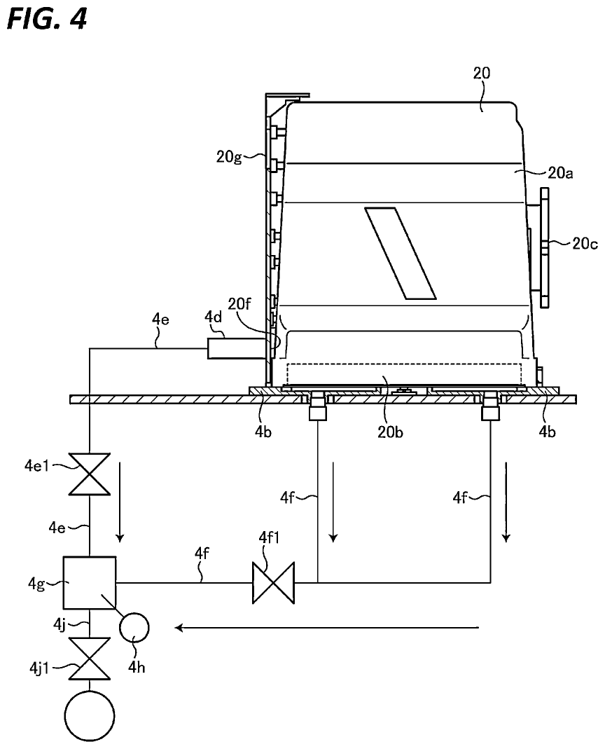

Next, an example of the configuration of the lock/unlock stage 4 according to the present embodiment is described. FIGS. 2, 3, and 4 are views illustrating an example of the configuration of the lock/unlock stage 4 according to the embodiment. FIGS. 2 and 3 are perspective views of the lock/unlock stage 4 according to the embodiment. FIG. 2 illustrates a state where the FOUP 20 is not disposed on the lock/unlock stage 4, and FIG. 3 illustrates a state where the FOUP 20 is disposed on the lock/unlock stage 4. In addition, FIG. 4 is a side view of the lock/unlock stage 4 according to the embodiment.

As illustrated in FIGS. 2, 3, and 4, the lock/unlock stage 4 includes two latch keys 4a, two frames 4b, a gas supply nozzle 4c, a gas exhaust nozzle 4d, a pipe 4e, a pipe 4f, and a collection box 4g.

The latch key 4a rotates while being inserted into a keyhole formed in the door 20b of the FOUP 20, thereby separating the FOUP 20 into the shell 20a and the door 20b, or connecting the shell 20a and the door 20b. For example, when the keyhole of the door 20b is a rectangular recess, the latch key 4a has a so-called T-shape with its head formed into a rectangular parallelepiped corresponding to the keyhole of the door 20b.

The two frames 4b have a so-called U-shape facing each other in a plan view. The two frames 4b are provided with the open sides of the U-shape facing each other, and the approximately annular shape formed by the two frames 4b has a size corresponding to the outer shape of the door 20b. The door 20b is disposed on the annular shape formed by the two frames 4b. The two frames 4b are separated by a predetermined distance. Therefore, two gaps 4b1 are formed between the two frames 4b, and the gaps 4b1 are used as spaces for the robot arm 3a of the robot 3 to enter when the robot arm 3a disposes the door 20b on the frame 4b.

The disposition surface of the door 20b is not limited to the shape of the two U-shaped frames 4b. For example, the frame may be a rectangular frame that does not have the gap 4b1, which is the space for the robot arm 3a to enter. When the FOUP 20 is disposed on the two U-shaped frames 4b, if a gap between the shell 20a and the door 20b exists in the gap 4b1 (the space for the robot arm 3a to enter), gas will leak from there. However, when the frame is a rectangular frame without the gap 4b1, gas leakage may be minimized. At this time, when only the door 20b is held by the robot hand 3b, a mechanism may be newly provided to raise the door 20b, thereby raising the door 20b.

In the embodiment, after the FOUP 20 has been main-dried in the drying chamber 6, the robot 3 first grasps the door 20b from the drying chamber 6 and transports the door 20b to the frame 4b of the lock/unlock stage 4, and then disposes the door 20b on the frame 4b. Next, the robot 3 grasps and transports the shell 20a to the frame 4b, and disposes the shell 20a on the door 20b. At this time, the robot 3 disposes the shell 20a on the door 20b in a state where the shell 20a is positioned with respect to the door 20b.

When the shell 20a is disposed on the door 20b, the latch key 4a connects the shell 20a and the door 20b. As a result, the lock/unlock stage 4 disposes the FOUP 20 such that the door 20b is disposed on the disposition surface (the upper surface of the frame 4b) in a state where the door 20b and the shell 20a are attached. In addition, the lock/unlock stage 4 has a detachment function for locking/unlocking the door 20b with respect to the shell 20a when the door 20b is disposed on the disposition surface.

Here, a groove 4b2 is formed in the frame 4b. In addition, in the embodiment, a gap 20d is formed between the shell 20a and the door 20b in a state where the shell 20a and the door 20b are connected. In the embodiment, the groove 4b2 is formed in the frame 4b such that the space formed by the groove 4b2 communicates with the space of the gap 20d in a state where the FOUP 20 is disposed on the frame 4b. As illustrated in FIG. 2, the groove 4b2 is open only on the upper surface side of the frame 4b, and the end of the frame 4b on the gap 4b1 side is closed. That is, when the FOUP 20 is disposed on the upper surface of the frame 4b, the groove 4b2 is completely blocked.

As illustrated in FIG. 3, a gas supply port 20e and a gas exhaust port 20f are provided on the bottom surface 20g of the shell 20a, i.e., the surface (intersecting surface) 20g intersecting with a surface having an opening. In the state where the FOUP 20 is disposed on the frame 4b, the gas supply nozzle 4c is coupled (connected) to the gas supply port 20e, and the gas exhaust nozzle 4d is inserted into the gas exhaust port 20f. That is, the gas supply nozzle 4c and the gas exhaust nozzle 4d are disposed at positions corresponding to the gas supply port 20e and the gas exhaust port 20f when the FOUP 20 is disposed on the frame 4b.

The gas supply nozzle 4c is connected to a gas tank in which an inert gas such as N₂ is stored, and supplies the inert gas supplied from the gas tank to the storage space of the shell 20a via the gas supply port 20e. In this manner, the gas supply nozzle 4c supplies the inert gas to the storage space of the FOUP 20 disposed on the lock/unlock stage 4, thereby replacing the gas in the storage space. The gas supply nozzle 4c and the gas tank are an example of a gas supply.

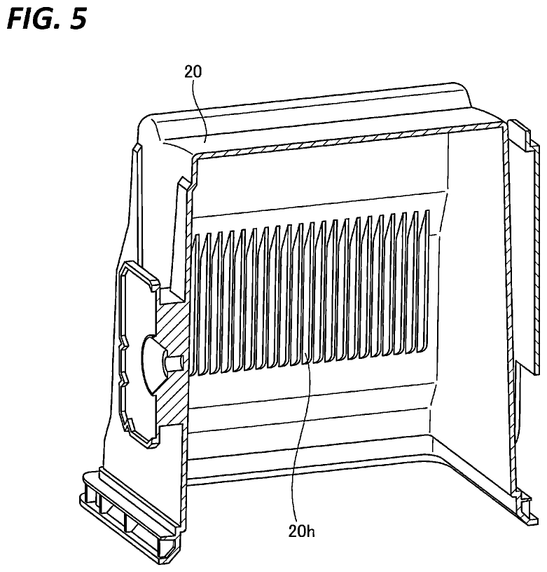

As described above, the bottom surface 20g of the FOUP 20 (shell 20a) is provided with a gas supply port 20e for supplying a gas. When the FOUP 20 is disposed such that the door 20b is disposed on the upper surface of the frame 4b, which is the disposition surface, the bottom surface 20g of the FOUP 20 (shell 20a) on which the gas supply port 20e is provided is located on the left side of FIG. 4. Thus, when the FOUP 20 is disposed on the frame 4b, which is the placement surface, as illustrated in FIG. 5, a slot (shelf) 20h of the shell 20a, which has a planar shape on which the semiconductor wafer is disposed, extends vertically. Therefore, when dust adheres to the slot 20h in the shell 20a, the dust is easily moved to the door 20b side located below because gravity acts on the dust in addition to the momentum of the gas supply, and the dust may be prevented from remaining in the slot 20h. FIG. 5 is a view for explaining an example of an arrangement of slots 20h according to an embodiment.

In addition, As illustrated in FIG. 4, the gas present in the storage space of the shell 20a is discharged through the gas discharge nozzle 4d via the gas discharge port 20f. The gas discharge nozzle 4d is connected to a pipe 4e, which is connected to a collection box 4g. Thus, the gas discharged from the storage space of the shell 20a flows into the collection box 4g via the gas discharge port 20f, the gas discharge nozzle 4d, and the pipe 4e. In this way, the collection box 4g collects the gas discharged from the storage space. In addition, a valve 4e1 is provided on the path through which the gas flows in the pipe 4e, and the valve 4e1 adjusts the inflow of the gas into the collection box 4g by its opening and closing.

In addition, the groove 4b2 is connected to a pipe 4f for gas collection provided on the opposite side to the side where the frame 4b is provided. That is, the space formed by the groove 4b2 is connected to the space in the pipe 4f. The pipe 4f is connected to the collection box 4g. The gas present in the groove 4b2 flows into the collection box 4g through the pipe 4f. Therefore, the gas leaking from the gap 20d between the shell 20a and the door 20b flows into the collection box 4g through the groove 4b2 and the pipe 4f. In this way, the collection box 4g collects the gas leaking from the gap 20d. In addition, a valve 4f1 is provided on the path through which the gas flows in the pipe 4f, and the valve 4f1 adjusts the inflow of the gas into the collection box 4g by its opening and closing. The valve 4f1 is provided between the collection box 4g and the point where the two pipes 4f that collect gas from the groove 4b2 join together.

In the groove 4b2, an inert gas is discharged from the storage space of the shell 20a through the gap 20d. Therefore, the space formed by the groove 4b2 gradually becomes positive pressure due to the discharged gas. The gas in the groove 4b2 is pushed by the positive pressure and guided to the collection box 4g. A suction source such as a pump may be provided at the end of the pipe 4f, so that the gas is actively collected by the collection box 4g. By suctioning with the suction source in this way, the gas replacement efficiency may be improved.

Here, as described above, due to the small gap 20d between the door 20b and the shell 20a, gas leaks from the storage space through the gap 20d as the replacement of the gas in the storage space progresses. The leaking gas contains oxygen similar to the air in the clean room in which the wafer storage container processing apparatus 1 is installed, and also contains moisture similar to the air in the clean room, immediately after the start of gas supply. However, as time passes after the start of supply, the inert gas supplied from the gas supply nozzle 4c gradually leaks out from the gap 20d.

The collection box 4g collects the gas and stores the collected gas. For example, the collection box 4g collects the gas leaking from the gap 20d and the gas discharged from the gas discharge port 20f. That is, the collection box 4g collects gases in which the gas leaking from the gap 20d and the gas discharged from the gas discharge port 20f are mixed (mixed gas). In this way, the collection box 4g collects the gas leaking from the gap 20d between the shell 20a and the door 20b, which is present in the storage space to be replaced by the inert gas supplied from the gas supply nozzle 4c. In addition, the collection box 4g collects the gas discharged from the gas discharge port 20f, which is present in the storage space to be replaced by the inert gas supplied from the gas supply nozzle 4c. The collection box 4g, the gas discharge port 20f, the pipes 4e, 4f, and the valves 4e1, 4f1 are an example of a gas collector.

The collection box 4g includes a measurement unit 4h therein that measures the oxygen concentration of the gas stored in the collection box 4g. The measurement unit 4h is an example of a gauge. The measurement unit 4h measures the oxygen concentration at a predetermined time interval and transmits the measured oxygen concentration to the control unit 8. The measurement unit 4h is, for example, an oxygen concentration meter that measures the oxygen concentration of the gas and transmits the measured oxygen concentration to the control unit 8. The measurement unit 4h may be, for example, a hygrometer. In this case, the hygrometer measures the humidity of the gas and transmits the measured humidity to the control unit 8.

In addition, a pipe 4j for exhausting the collected gas is connected to the collection box 4g. Further, a valve 4j1 is provided on the path through which the gas flows in the pipe 4j. When the collected gas is exhausted, the gas flows through the pipe 4j in a state where the valve 4j1 is open. Here, a suction source such as a pump may be provided at the end of the pipe 4j so that the gas is actively exhausted. By suctioning with the suction source in this manner, the gas exhaust efficiency may be improved.

The control unit 8 according to the present embodiment controls the supply of an inert gas to the storage space based on the measured value transmitted from the measurement unit 4h. For example, the control unit 8 compares the measured value with a predetermined value, and when the measured value is equal to or greater than the predetermined value, controls the gas supply nozzle 4c such that the supply of the inert gas is continued. Meanwhile, when the measured value is below the predetermined value, it is considered that the storage space of the shell 20a is filled with the inert gas, and the control unit 8 controls the gas supply nozzle 4c such that the supply of the inert gas from the gas supply nozzle 4c is stopped. To explain with a specific example, the control unit 8 compares the oxygen concentration with a first predetermined value, and when the oxygen concentration is below the first predetermined value, controls the gas supply nozzle 4c so as to stop the supply of the inert gas. In addition, the control unit 8 compares the humidity with a second predetermined value, and when the humidity is below the second predetermined value, controls the gas supply nozzle 4c so as to stop the supply of the inert gas. The specified values (first specified value and second specified value) are oxygen concentration values and humidity values that create an environment in which the components in the storage space may be maintained without oxidizing, and such oxygen concentration values and humidity values are determined in advance through experiments, simulations, and the like.

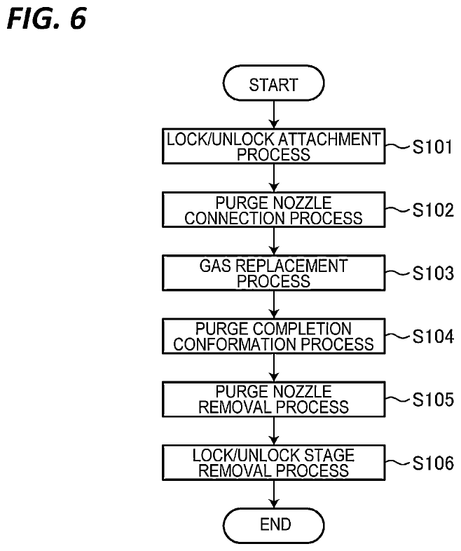

Next, an example of a purging process performed by the wafer storage container processing apparatus 1 according to the present embodiment is described. FIG. 6 is a flowchart illustrating an example of a purging process performed by the wafer storage processing apparatus 1 according to an embodiment. The purging process illustrated in FIG. 6 is performed when the vacuum drying of the FOUP 20 in the drying chamber 6 is completed.

In a lock/unlock attachment process in step S101 of the purging process illustrated in FIG. 6, the robot 3 separately transports the shell 20a and the door 20b in the drying chamber 6 onto the lock/unlock stage 4. Then, the lock/unlock stage 4 connects the shell 20a and the door 20b.

Next, in a purge nozzle connection process of step S102, the gas supply nozzle 4c is connected to the gas supply port 20e, and the gas exhaust nozzle 4d is inserted into the gas exhaust port 20f, while the FOUP 20 is disposed on the frame 4b.

Next, in the gas replacement process of step S103, the gas supply nozzle 4c starts to supply the inert gas to the storage space of the shell 20a, thereby starting to replace the gas in the storage space. In step S103, the control unit 8 opens the valves 4e1 and 4f1 and closes the valve 4j1. As a result, the collection box 4g starts to collect the above-mentioned mixed gas.

Next, in the purge completion confirmation process of step S104, when the measured value transmitted from the measurement unit 4h is equal to or greater than the predetermined value, the control unit 8 controls the gas supply nozzle 4c to continue the supply of the inert gas. Meanwhile, when the measured value is below the predetermined value, it is considered that the storage space of the shell 20a is filled with the inert gas, and the control unit 8 controls the gas supply nozzle 4c such that the supply of the inert gas is stopped.

When the supply of inert gas is stopped, in a purge nozzle removal process of step S105, the gas supply nozzle 4c is removed from the gas supply port 20e, and the gas exhaust nozzle 4d is removed from the gas exhaust port 20f, while the FOUP 20 is disposed on the frame 4b.

Then, in a lock/unlock stage removal process of step S106, the robot 3 removes the FOUP 20 from the lock/unlock stage 4, and transports the removed FOUP 20 to the unload port 7. Then, the FOUP 20 is carried out from the wafer storage container processing apparatus 1.

The wafer storage container processing apparatus 1 according to the embodiment has been described above.

Here, an example of a conventional wafer storage container processing apparatus and a conventional FOUP are described. Conventionally, there is a technology for supplying an inert gas into a FOUP to replace the gas in the FOUP. However, when there is a small gap between the shell and the door, the gas replacement may not be performed efficiently. Furthermore, since this gap differs depending on the individual FOUP, it is not possible to detect whether the gas replacement in each FOUP has been sufficiently performed. In addition, it is possible to perform a control such that the time when the gas replacement in the FOUP is expected to be completed is set as a predetermined time, and the replacement of the gas in the FOUP is determined to be completed when the predetermined time has elapsed since the start of the supply of the inert gas. However, when performing such a control, the predetermined time needs to be set to a time when the replacement is surely completed, so that it needs to be set longer. As a result, the supply of the inert gas is performed for a longer time than the time when the replacement is actually completed, which results in waste in terms of cost and processing time.

Furthermore, the conventional FOUP is provided with both a gas supply port for supplying an inert gas such as N₂ gas, and a gas exhaust port for exhausting a gas, and it is thought that it is possible to detect whether gas replacement is complete by measuring the gas exhausted from the gas exhaust port. However, since both of the ports are provided on the same surface of the FOUP (the bottom surface of the FOUP, i.e., the surface that intersects with the surface of the opening where the door is attached) and the two ports are provided close to each other, a relatively large amount of the inert gas may be exhausted from the gas exhaust port even when the gas replacement inside the FOUP is not complete.

In addition, in the conventional FOUP, a large amount of inert gas is discharged from the gap between the door and the shell of the FOUP, and measurement may not be possible when only a small amount of gas is discharged from the gas discharge port. Therefore, even with this method, it is difficult to detect the gas replacement state inside the FOUP.

Meanwhile, in the case of the present embodiment where the FOUP 20 is disposed on the lock/unlock stage 4 with the door 20b facing downwards during the purging process, the weight of the shell 20a presses the door 20b against the frame 4b, bringing the shell 20a and the door 20b into close contact with each other, thereby reducing the size of the gap 20d. Therefore, the amount of gas leaking from the gap 20d may be reduced. As a result, replacement of the gas in the FOUP 20 may be efficiently performed.

In addition, in the wafer storage container processing apparatus 1 of the embodiment, the FOUP 20 is arranged such that the shell 20a and the door 20b are connected and the door 20b is disposed on the frame 4b. Therefore, the oxygen concentration and humidity in the storage space may be measured even when more gas comes out of the gap 20d between the door 20b and the shell 20a than comes out of the gas exhaust port 20f.

Further, as described above, by disposing the FOUP 20 on the lock/unlock stage 4 with the door 20b facing downwards and performing the purging process, the slot 20h of the shell 20a is disposed to extend vertically. Therefore, gravity acts on the debris in addition to the force of the gas supply, so that the debris in the slot 20h tends to move towards the door 20b, thereby preventing debris from remaining in the slot 20h.

Furthermore, if the FOUP 20 were disposed such that the gas supply port 20e and the gas exhaust port 20f were on the bottom, it would be necessary to provide a member that covers the entire door 20b in order to catch any gas that leaks through the gap 20d. However, according to the embodiment, the disposition surface of the lock/unlock stage 4 also serves to cover the door 20b. Thus, it is only necessary to provide an additional frame 4b that covers the gap 20d.

As described above, according to the embodiment, gas replacement within the FOUP 20 may be efficiently performed.

Furthermore, compared to the conventional method of measuring only the gas discharged from one gas exhaust port, the method of the embodiment measures the gas leaking from gap 20d in addition to gas exhaust port 20f, thereby improving the reliability of the measurement.

In addition, since the lock/unlock stage 4 has a function for attaching (connecting) the door 20b and shell 20a of the FOUP 20, gas replacement and attachment of the door 20b and shell 20a may be performed at the same time and in the same place, enabling efficient purging processing.

### Modification of Embodiment

Next, a modification of the embodiment will be described. In the following description of the modification, configurations different from the above-described embodiment will be mainly described, and descriptions of configurations similar to the above-described embodiment may be omitted.

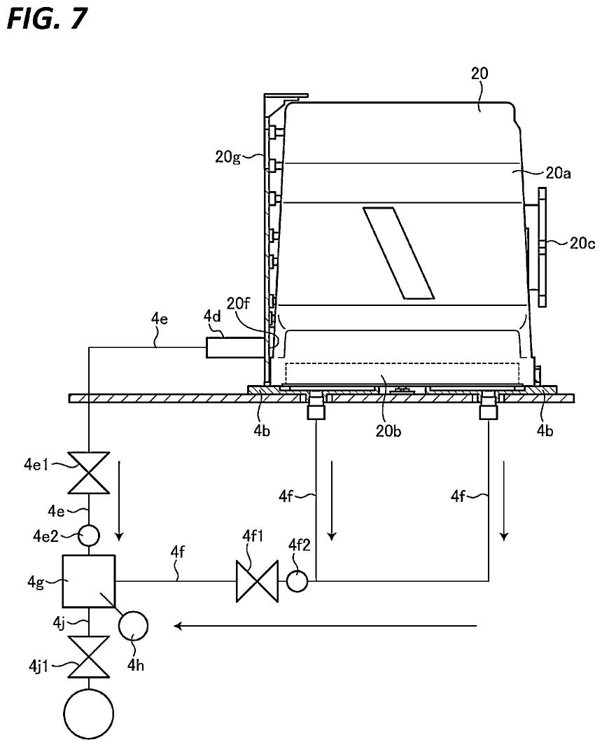

FIG. 7 is a side view of the lock/unlock stage 4 according to a modification of the embodiment. The lock/unlock stage 4 according to the modification illustrated in FIG. 7 differs from the lock/unlock stage 4 according to the embodiment illustrated in FIG. 4 in that a flow meter 4e2 and a flow meter 4f2 are further provided. In addition, although not illustrated in FIG. 7, the lock/unlock stage 4 according to the modification also includes a flow meter (supply gas flow meter) provided on a gas flow path of the pipe connecting the gas tank and the gas supply nozzle 4c.

The flow meter 4e2 is provided on the path through which the gas flows in the pipe 4e, measures the flow rate of the gas discharged from the gas exhaust port 20f and flowing into the collection box 4g at predetermined time intervals, and transmits the measured flow rate to the control unit 8.

The flow meter 4f2 is provided on the path through which the gas flows in the pipe 4f, measures the flow rate of the gas discharged from the gas exhaust port 20d and flowing into the collection box 4g at predetermined time intervals, and transmits the measured flow rate to the control unit 8.

The supply gas flow meter measures the flow rate of the gas supplied from the gas tank to the gas supply nozzle 4c at predetermined time intervals, and transmits the measured flow rate to the control unit 8.

The control unit 8 according to the modification performs various controls based on the flow rates transmitted from the flow meters 4e2 and 4f2 and the supply gas flow meter. For example, the control unit 8 performs control so as to output information indicating that gas is leaking according to the received flow rate every time the control unit 8 receives the flow rate transmitted from the flow meter 4f2.

To explain with a specific example, the control unit 8 compares the flow rate from the flow meter 4f2 with a predetermined threshold value, and when the flow rate from the flow meter 4f2 is equal to or greater than the predetermined threshold value, the control unit 8 displays information indicating that gas is leaking from the gap 20d on a display connected to the control unit 8, thereby outputting the information. An example of the information indicating that gas is leaking from the gap 20d is a text data message saying, for example, “Gas is leaking.” In addition, when the flow rate from the flow meter 4f2 is equal to or greater than the predetermined threshold value, the control unit 8 transmits information indicating that gas is leaking and the flow rate from the flow meter 4f2 together with an identification (ID) for identifying the FOUP 20 placed on the lock/unlock stage 4 to an external server that collectively manages the FOUPs 20. As a result, the information and the flow rate from the flow meter 4f2 are output to the external server. Then, the external server stores the ID, the information indicating that gas is leaking, and the flow rate of the leaking gas in association with each other. In addition, the history of gas leakage amounts for the FOUP 20 with the same ID may be recorded, and when the leakage amount increases over time, when the rate of increase exceeds a predetermined rate, or when the leakage amount exceeds a predetermined threshold, information to discontinue use of the FOUP 20 may be stored in association with the ID.

In addition, the control unit 8 compares the total value of the flow rate from the flow meter 4f2 and the flow rate from the flow meter 4e2 with the flow rate from the supply gas flow meter. Then, when the flow rate from the supply gas flow meter is greater than the total value, the control unit 8 determines that the gas may be leaking from a location other than the gas exhaust port 20f. Thus, when the flow rate from the supply gas flow meter is greater than the total value, the control unit 8 displays information indicating that the gas may be leaking, on the display. For example, an example of information indicating that the gas may be leaking is a text data message saying “Gas may be leaking from a location other than the exhaust port.” In addition, when the flow rate from the supply gas flow meter is greater than the total value, the control unit 8 transmits information indicating that the gas may be leaking, together with an ID for identifying the FOUP 20 disposed on the lock/unlock stage 4 to an external server that collectively manages the FOUPs 20. As a result, the external server stores the ID and the information indicating that the gas may be leaking, in association with each other.

According to the modification, the user of the wafer storage container processing apparatus 1 may properly grasp the status of various gas leaks. Accordingly, the user may determine whether to continue using the FOUP 20 according to the gas leak status.

From the foregoing, it will be appreciated that various embodiments of the present disclosure have been described herein for purposes of illustration, and that various Modifications may be made without departing from the scope and spirit of the present disclosure. Accordingly, the various embodiments disclosed herein are not intended to be limiting, with the true scope and spirit being indicated by the following claims.

What is claimed is:

1. A wafer storage container processing apparatus that processes a wafer storage container including a body having a storage space connected to an opening and a door detachable from the opening, the wafer storage container processing apparatus comprising:
a stage having a disposition surface on which the wafer storage container is disposed; and
a gas supply configured to supply an inert gas to the wafer storage container disposed on the stage,
wherein the stage disposes the wafer storage container thereon such that the door is disposed on the disposition surface in a state where the door is attached to the body, and
the gas supply supplies the inert gas through a gas supply port provided on an intersecting surface of the body that intersects a surface having the opening.

2. The wafer storage container processing apparatus according to claim 1, wherein the stage has a detachable function for locking/unlocking the door with respect to the body when the door is disposed on the disposition surface.

3. The wafer storage container processing apparatus according to claim 1, further comprising:
a gas collector configured to collect, into a box, a gas present in the storage space that is replaced by the inert gas supplied from the gas supply and that leaks from a gap between the body and the door;
a gauge configured to measure at least one of an oxygen concentration and a humidity of the gas in the box; and
a controller configured to control the gas supply and the gauge,
wherein the controller controls the gas supply to stop supplying the inert gas from the gas supply when at least one of the oxygen concentration and the humidity measured by the gauge falls below a predetermined value.

4. The wafer storage container processing apparatus according to claim 1, further comprising:
a cleaning section configured to clean the storage space in a state where the body and the door are separated from each other,
wherein the gas supply supplies the inert gas to the wafer storage container disposed on the stage after cleaning by the cleaning section.

5. The wafer storage container processing apparatus according to claim 3, wherein the gas collector further collects a gas discharged from a gas discharge port provided on the intersecting surface, and
the gauge measures at least one of the oxygen concentration and the humidity of a mixed gas of the gas leaking from the gap and the gas discharged from the gas discharge port, which is collected by the gas collector.

6. The wafer storage container processing apparatus according to claim 3, further comprising:
a flow meter configured to measure a flow rate of the gas leaking from the gap,
wherein, when the flow rate of the gas is equal to or greater than a predetermined threshold, the control unit outputs information indicating that gas is leaking.
